(19) United States
(12) Patent Application Publication
(10) Pub. No.: US 2012/0266818 A1
(43) Pub. Date: Oct. 25, 2012

(54) ATMOSPHERIC FILM-COATING DEVICE AND FILM-MANUFACTURING APPARATUS

(75) Inventors: Yih-Ming SHYU, TAINAN CITY (TW); Yan-Gen CHEN, TAICHUNG CITY (TW); Shih-Ming HUANG, CHANGHUA COUNTY (TW); Chun-Chia YEH, TAINAN CITY (TW); Pei-Lin CHEN, TAINAN CITY (TW); Shih-Huan LIN, TAINAN CITY (TW)

(73) Assignee: CREATING NANO TECHNOLOGIES, INC., TAINAN CITY (TW)

(21) Appl. No.: 13/300,640

(22) Filed: Nov. 20, 2011

(30) Foreign Application Priority Data
Apr. 21, 2011 (TW) 100207065

(51) Int. Cl. C23C 16/448; C23C 16/50; C23C 16/52; C23C 16/455

(52) U.S. Cl. 118/712; 118/726; 118/720; 118/723 R

(57) ABSTRACT

An atmospheric film-coating device and a film-manufacturing apparatus are described. The atmospheric film-coating device includes a delivery device and a nebulization device. The delivery device is suitable for delivering at least one substrate. The nebulization device is used to gasify a film coating solution toward a direction indirectly to the at least one substrate into a plurality of film coating vapor molecules to deposit on a surface of the at least one substrate.

### RELATED APPLICATIONS

This application claims priority to Taiwan Application Serial Number 100207065, filed Apr. 21, 2011, which is herein incorporated by reference.

### FIELD OF THE INVENTION

The present invention relates to a coating device, and more particularly to an atmospheric film-coating device and a film-manufacturing apparatus.

### BACKGROUND OF THE INVENTION

As portable electronic devices are progressively popularized, protection requirements to outer surfaces of the portable electronic devices are increased. Currently, in order to protect the outer surface of the electronic device, a film, such as an anti-smudge film, is usually coated on the outer surface of the electronic device. In general, the film covering the surface has properties of good anti-smudge, anti-fingerprint, smooth, waterproof, oleo-phobic and transparent. In addition, the film must have high adhesion to an outer surface of a device to prolong the use life of the film.

For example, a surface of a touch screen of a popular touch electronic device is usually coated with an anti-fingerprint film to keep good display quality and operation sensitivity after being touched and rubbed many times.

Currently, there are four main methods for coating a film on a surface of a substrate. The first method is a vacuum evaporation method. In the method, a coating is heated underneath a substrate in a vacuum chamber to gasify to arise and adhere to the lower surface of the substrate to form a film. However, the coating method needs to vacuum an evaporation chamber, so that the process time is increased, the throughput is poor, and the method is unsuitable for a substrate surface, which needs to be continuously evaporated.

The second method is a dipping coating method. In the method, a substrate is dipped in a film coating solution to make it coated with the coating after taking it out. However, with regard to the coating of a continuous substrate, the required apparatus would be large, so that the method is unsuitable for the continuous substrate.

The third method is a spray coating method. In the method, a film coating is sprayed directly toward a surface of a substrate to form a film. However, most of the coating spray contacts the surface of the substrate before being gasified, so that droplets drip on the surface of the substrate. As a result, the coated film has poor uniformity.

The fourth method is a brush coating method, which directly coats a film onto a surface of a substrate by a brush. However, the coating method usually causes a reduplicated coating phenomenon between two adjacent brushing areas, so that the film has poor uniformity.

Therefore, an apparatus, which can coat a film on the surfaces of a big amount of substrates rapidly and uniformly, is needed.

### SUMMARY OF THE INVENTION

Therefore, one aspect of the present invention is to provide an atmospheric film-coating device and a film-manufacturing apparatus of a film, which can coat the film under an atmospheric environment, so that the throughput can be highly increased.

Another aspect of the present invention is to provide an atmospheric film-coating device, which can coat films onto continuous substrates effectively.

Still another aspect of the present invention is to provide an atmospheric film-coating device, which can coat film on the surface of a big amount of substrate rapidly and uniformly.

According to the aforementioned aspects, the present invention provides an atmospheric film-coating device, which includes a delivery device and a nebulization device. The delivery device is suitable for delivering at least one substrate. The nebulization device is used to gasify a film coating solution toward a direction indirectly to the at least one substrate into a plurality of film coating vapor molecules to deposit on a surface of the at least one substrate.

According to one embodiment of the present invention, the atmospheric film-coating device further includes a protective cover suitable for covering the at least one substrate and the nebulization device. The protective cover and the delivery device define a confined space or a semi-confined space.

According to another embodiment of the present invention, the nebulization device includes at least one coating carrier suitable for carrying a film coating solution, and at least one nebulization element disposed on the at least one coating carrier and suitable for gasifying the film coating solution into the film coating vapor molecules.

According to another embodiment of the present invention, the at least one nebulization element may include an ultrasonic nebulization vibration sheet, a heating evaporation nebulization element, a high-pressure gas jet element or a nozzle nebulization element.

According to another embodiment of the present invention, the at least one nebulization element is set on the top portion of the at least one coating carrier, and the nebulization device includes at least one coating-conducting element suitable for inducing the film coating solution to the at least one nebulization element.

According to yet another embodiment of the present invention, the at least one coating carrier includes a plurality of coating carriers, and the at least one nebulization element includes one single nebulization element disposed on the coating carriers.

According to still further another embodiment of the present invention, the at least one coating carrier includes one single coating carrier, and the at least one nebulization element includes a plurality of nebulization elements set on the coating carrier.

According to still yet another embodiment of the present invention, the delivery device includes a carrier suitable for carrying the at least one substrate.

According to the aforementioned purposes, the present invention further provides a film-manufacturing apparatus. The film-manufacturing apparatus of the film includes a delivery device, a plasma device and an atmospheric coating device. The delivery device is suitable for delivering at least one substrate. The plasma device is set on a top of the delivery device and is suitable for performing a surface activation treatment on a surface of the at least one substrate. The atmospheric coating device is adjacent to the plasma device. The atmospheric coating device includes a nebulization device used to gasify a film coating solution toward a direction indirectly to the surface of the at least one substrate into a plurality of film coating vapor molecules to deposit and form a film on the surface of the at least one substrate which has been activated as aforementioned.

According to one embodiment of the present invention, the manufacturing apparatus of the film further includes a protective cover suitable for covering the at least one substrate and the nebulization device. The protective cover and the delivery device define a confined space or a semi-confined space.

According to another embodiment of the present invention, the nebulization device includes at least one coating carrier suitable for carrying a film coating solution, and at least one nebulization element disposed on the at least one coating carrier and suitable for gasifying the film coating solution into the film coating vapor molecules.

According to still another embodiment of the present invention, the plasma device is an atmospheric plasma device, a low-pressure plasma device or an electromagnetically coupled plasma device.

According to further embodiment of the present invention, the atmospheric coating device includes a coating quantity sensor suitable for sensing a quantity of the film coating solution received in the at least one coating carrier.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1 is a schematic diagram showing a nebulization device of an atmospheric film-coating device in accordance with an embodiment of the present invention;

FIG. 2 is a schematic diagram showing the installation of the atmospheric film-coating device in FIG. 1; and

FIG. 3 is a schematic diagram showing a film-manufacturing apparatus in accordance with an embodiment of the present invention.

### DETAILED DESCRIPTION OF THE PREFERRED EMBODIMENT

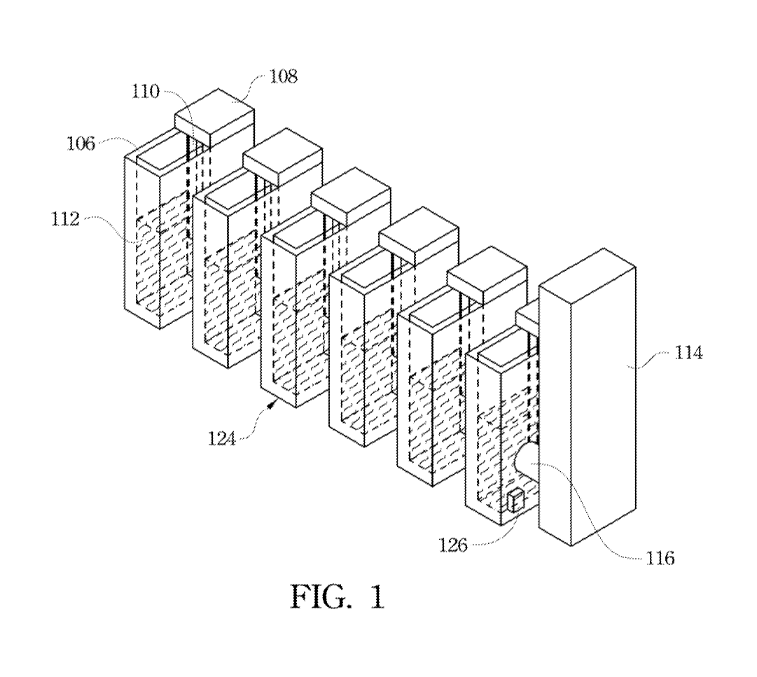

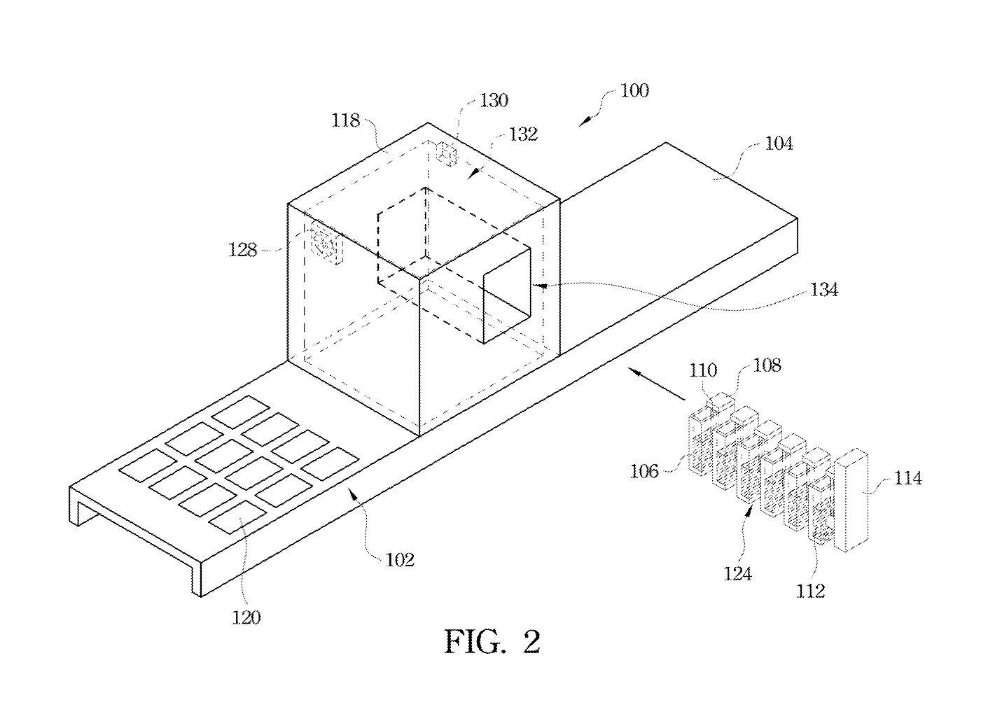

FIG. 1 is a schematic diagram showing a nebulization device of an atmospheric coating device of a film in accordance with an embodiment of the present invention, and FIG. 2 is a schematic diagram showing the installation of the atmospheric coating device of the film in FIG. 1. An atmospheric film-coating device 100 of the present embodiment may be applied in manufacturing an anti-smudge film, an ITO film and a PEDOT:PSS film, for example.

In the present embodiment, as shown in FIG. 2, the atmospheric coating device 100 mainly includes a delivery device 102 and a nebulization device 124. In some examples, as shown in FIG. 1, the nebulization device 124 may include one or more coating carriers 106 and one or more nebulization elements 108. The delivery device 102 is used to deliver one or more substrates 120, as shown in FIG. 2. In the exemplary example shown in FIG. 2, the delivery device 102 may include a carrier 104, and the substrates 120 may be put on the carrier 104 and delivered by the delivery device 102. The substrate 120 may be a protective glass, a plastic substrate, a tempered glass or a metal substrate, for example. The nebulization device 124 is used to nebulize a film coating solution 112 and sprays the nebulized film coating solution 112 toward a direction indirectly to the substrate 120.

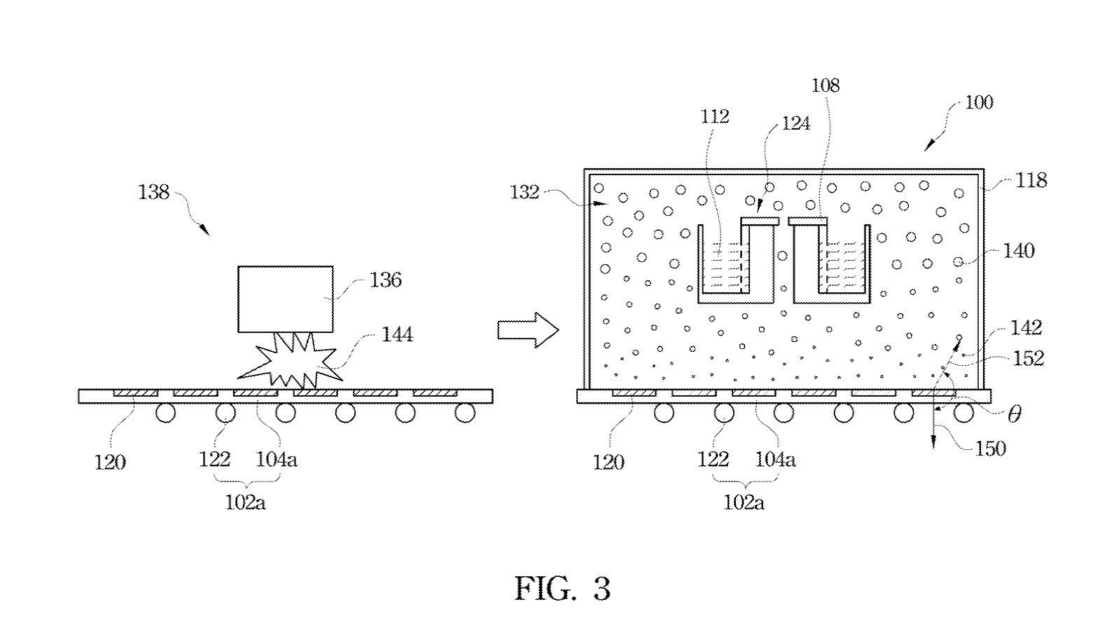

In one embodiment, as shown in FIG. 3, the film coating solution 112 is gasified toward a direction 152, and an included angle θ between the direction 152 and a gravitational direction 150 of the substrate 120 may range from 10 degrees to 180 degrees. In another embodiment, the included angle θ between the direction 152 and the gravitational direction 150 of the substrate 120 may range from 100 degrees to 170 degrees.

In another example, as shown in FIG. 3, a delivery device 102a includes a carrier 104a and several rollers 122. The rollers 122 are disposed beneath the carrier 104a and can drive the carrier 104a. In still another examples, the substrate may be a continuous substrate, and the delivery device may be a delivery device, which can drive the continuous substrate, such as two rollers disposed on both front and back sides of the nebulization device 124 to support and drive the continuous substrate forward. In this case, a delivery strap is not needed for carrying the substrate.

Referring to FIG. 1 again, each coating carrier 106 may carry a film coating solution 112. In addition, as shown in FIG. 2, the coating carriers 106 are disposed over the substrates 120. The film coating solution 112 may include a film coating and a solvent. In one example, the film coating solution 112 including anti-smudge coating molecules are used when coating an anti-smudge film. The anti-smudge coating molecules may include F—C—Si hydrocarbon compound, perfluorocarbon-Si (PFC—Si) hydrocarbon compound, F—C—Si alkane compound, PF—Si alkane compound or PF—Si alkane ether compound. In another example, when coating an ITO film, a solution including indium and tin precursors is used as the film coating solution 112. In still another example, when coating a PEDOT:PSS film, a solution including PEDOT:PSS molecules is used as the film coating solution 112.

Furthermore, the solvent of the film coating solution 112 may include a high volatile liquid, water, or a liquid composed of a mixture of the high volatile liquid and water, for example. The high volatile liquid is in a liquid state at a room temperature, has a stable chemical structure, high volatility and a low boiling point, is transparent and colorless, and has no obvious harm to creatures. In a embodiment, a vapor pressure of the high volatile liquid is bigger than a vapor pressure of water at a room temperature, and the high volatile liquid may be selected from a group consisting of alcohol, ether, alkane, ketone, benzene, fluorine-containing alcohol, fluorine-containing ether, fluorine-containing alkane, fluorine-containing ketone and fluorine-containing benzene.

The nebulization element 108 is disposed on a top portion of one side of the coating carrier 106 to nebulize the film coating solution 112 above the substrates 120. After being treated by the nebulization element 108, the film coating solution 112 can be nebulized to a film coating solution mist. Subsequently, the solvent in the film coating solution mist is volatilized rapidly, and is gasified to film coating vapor molecules. For example, the nebulization element 108 may be an ultrasonic nebulization vibration sheet, a heating evaporation nebulization element, a high-pressure gas jet element or a nozzle nebulization element. In the present embodiment, as shown in FIG. 1 and FIG. 2, the nebulization element 108 is an ultrasonic nebulization vibration sheet.

In the example shown in FIG. 1 and FIG. 2, the nebulization device 124 may include at least one coating-conducting element 110. The coating-conducting element 110 is connected between the film coating solution 112 in the coating carrier 106 and the nebulization element 108 to convey the film coating solution 112 from the coating carrier 106 to the nebulization element 108. The coating-conducting element 110 may be a cotton sliver or a conducting pipe, for example. In another example, the nebulization element 108 may float on the film coating solution 112, and it is unnecessary for the nebulization device 124 to include a coating-conducting element.

In the example shown in FIG. 1 and FIG. 2, the nebulization device 124 includes a plurality of coating carriers 106, a plurality of nebulization elements 108 and a plurality of coating-conducting elements 110. In the nebulization device 124, each coating carrier 106 is correspondingly equipped with one nebulization element 108 and one coating-conducting element 110.

However, in another exemplary example, a nebulization device may include a plurality of coating carriers and one single nebulization element, which is disposed on these coating carriers. The film coating solution contained in the coating carriers can be conveyed to the nebulization element respectively through coating-conducting elements. Then, the film coating solution contained in all coating carriers can be nebulized through the nebulization element.

In another example, a nebulization device may include one single coating carrier and a plurality of nebulization elements, which are disposed on the coating carrier. The film coating solution contained in the coating carrier may be conveyed respectively to the nebulization elements through one or more coating-conducting elements. Then, the film coating solution contained in the coating carrier can be nebulized through the nebulization elements.

Referring to FIG. 1 again, according to the operation requirement, the nebulization device 124 may include a coating-supplying tank 114. The coating-supplying tank 114 can supply the film coating solution 112 to all coating carriers 106 through a delivery pipe 116. Moreover, in the nebulization device 124, because of the communicating tube principle, heights of liquid levels of the film coating solution in all coating carriers 106 are substantially the same. Therefore, in another example, according to the practical requirement, the atmospheric coating device 100 may include a coating quantity sensor 126 disposed on one of the coating carriers 106 to sense the quantity of the film coating solution 112 received in the coating carriers 106, as shown in FIG. 1. The quantity information sensed by the coating quantity sensor 126 may be directly shown on a display device disposed on an outer surface of the atmospheric coating device 100, or may be transmitted to a monitor system by a transmission line, for online workers to monitor the quantity of the film coating solution 112 in the coating carriers 106.

In the present embodiment, several nebulization devices 124 may be used to coat films on several substrates 124, which are arranged in a line, a row or an array, on the delivery device 102 simultaneously. Furthermore, in the present invention, the coating of the film is performed atmospherically, so that the film coating can be largely, rapidly, effectively and uniformly coated on the surface of the substrate 120.

Referring to FIG. 2 again, in the example, the atmospheric coating device 100 may further include a protective cover 118. The protective cover 118 covers a portion of the delivery device 102 and may define a reactive chamber 132 with the carrier 104 of the delivery device 102. In addition, the protective cover 118 covers the substrates 120 and the nebulization device 124, which includes the coating carriers 106, the nebulization elements 108 and the coating-conducting elements 110, on the covered portion of the delivery device 102. It is worthy of note that when a substrate is continuous, a protective cover and a covered portion of the substrate can directly define a reactive chamber. In one exemplary example, the protective cover 118 and the delivery device 102 define a confined space. In another exemplary example, the protective cover 118 and the delivery device 102 define a semi-confined space.

As shown in FIG. 2, a sidewall of the protective cover 118 may have an opening 134. An area of the opening 134 of the protective cover 118 may be slightly larger than an area of a side surface of the coating carrier 106, so that the nebulization device 124 can enter the reactive chamber 132 within the protective cover 118 through the opening 134 of the protective cover 118.

In one example, the nebulization device 124 may further include a heater 130. The heater 130 is disposed within the reactive chamber 132, such as on a surface of the protective cover 118 or on the delivery device 102 within the reactive chamber 132. The heater 130 may heat the film coating solution mist formed by the nebulization elements 108 to accelerate the conversion from the film coating solution mist to the film coating vapor molecules. For example, when the solvent of the film coating solution 112 is water or other liquid, which is not a high volatile liquid, the heater 130 may be used to facilitate the conversion from the film coating solution mist to the film coating vapor molecules.

In another example, according to process requirements, the nebulization device 124 may further include a convection device 128. Similarly, the convection device 128 may be disposed within the reactive chamber 132, such as on a surface of the protective cover 118 or on the delivery device 102 within the reactive chamber 132. Before the film coating vapor molecules deposited on the substrate 120, the convection device 128 can distribute the film coating vapor molecules within the reactive chamber 132 more uniformly. With the convection device 128, the film can be formed more uniformly, and the film can be successfully coated on various surfaces of a three-dimensional structure by the atmospheric coating device 100.

The atmospheric coating device of the present embodiment can be used to coat a film with the using of a plasma device. FIG. 3 is a schematic diagram showing a film-manufacturing apparatus in accordance with an embodiment of the present invention. In addition to the atmospheric coating device 100, a film-manufacturing apparatus 138 further includes a plasma device 136. In an embodiment, the atmospheric coating device 100 and the plasma device 136 may use a delivery device 102a collectively. However, in another example, the atmospheric coating device 100 and the plasma device 136 may also use different delivery devices to deliver substrates to be treated. The atmospheric coating device 100 and the plasma device 136 are both disposed over the delivery device 102a. The atmospheric coating device 100 is adjacent to the plasma device 136, so that after the substrate 120 is treated by the plasma device 136, the film can be atmospherically coated on the substrate 120 immediately.

The plasma device 136 is used to produce plasma 144. The plasma 144 is used to perform a cleaning and surface modification treatment on a surface of the substrate 120 to activate the surface of the substrate 120. In one example, after the surface of the substrate 120 is activated by the plasma 144, a plurality of functional groups can be formed on the surface of the substrate 120. In one example, the plasma device 136 may use working gas, such as nitrogen gas, argon gas, oxygen gas and air, to produce the plasma 144. After the surface treatment is performed by the plasma 144, the functional groups formed on the surface of the substrate 120 may include hydroxyl functional groups, hydronitrogen functional groups, and/or functional groups or dangling bonds that can be bonded with film coating vapor molecules, for example.

In one example, the plasma device 136 may be an atmospheric plasma device, a low-pressure plasma device or an electromagnetically coupled plasma device to form an atmospheric plasma or a low-pressure plasma to perform a cleaning and surface modification treatment on the surface of the substrate 120. The atmospheric plasma may be an atmospheric plasma jet (or plasma torch), a dielectric barrier discharge (DBD) plasma or an atmospheric glow discharge plasma, and the low-pressure plasma may be a vacuum plasma. It is worthy of note that in the present embodiment, the cleaning and activating of the surface of the substrate 120 is performed by the atmospheric plasma for an operation consistency with a subsequent atmospheric coating procedure to reduce process time.

When the manufacturing apparatus 138 is used to perform the coating of the film, one or more substrate 120 may be disposed on the delivery device 102a. The plasma 144 produced by the plasma device 136 is firstly used to perform a cleaning and surface modification treatment on the surface of the substrate 120 to activate the surface of the substrate 120 and to form a plurality of functional groups on the surface of the substrate 120.

Then, under an atmospheric environment, the nebulization device 124 of the atmospheric coating device 100 is used to nebulize the film coating solution 112 above the surface of the substrate 120 within the reactive chamber 132, so as to form a film coating solution mist 140 above the substrate 120. When the nebulization element 108 of the nebulization device 124 is used to nebulize the film coating solution 112, the high volatile solvent can drive the film coating of larger molecules, so that it can facilitate the nebulization of the film coating solution 112 to convert into the film coating solution mist 140. Subsequently, the solvent in the film coating solution mist 140 is volatilized rapidly, so that the film coating solution mist 140 is gasified to form film coating vapor molecules 142.

After the film coating solution 112 nebulized or gasified within the reactive chamber 132, the film coating solution mist 140 spreads within the reactive chamber 132. The solvent in the film coating solution mist 140 is volatilized easily, and the molecules of the film coating are heavier, so that the film coating solution mist 140 spread within the reactive chamber 132 is gasified to form the film coating vapor molecules 142 after the solvent is volatilized. The film coating vapor molecules 142 fall down and are deposited on the surface of the substrate 120 to form a film on the surface of the substrate 120.

By spraying the nebulized film coating solution 112 indirectly to the substrate 120, it can provide sufficient volatilization time for the solvent in the film coating solution mist 140, and it also can provide a sufficient spreading distance for the sprayed film coating solution mist 140, thereby enhancing the film-coating uniformity.

In the embodiment, the surface of the substrate 120 has functional groups after being activated, so that the film coating molecules in the film coating solution mist 140 adhere to the surface of the substrate 120 in an anisotropic manner and has a condensation reaction with the functional groups on the surface of the substrate 120. As a result, a strong adhesive force is formed between the formed film and the surface of the substrate 120. In some examples, the film may be an anti-smudge film, an ITO film or a PEDOT:PSS film. The PEDOT:PSS film is typically used in an organic light emitting diode (OLED) or an organic solar cell.

In an embodiment of coating the ITO film, after the film coating vapor molecules 142 including indium and tin precursors are deposited on the surface of the substrate 120, energy may be provided to the indium and tin precursors pre-coated on the surface of the substrate 120 by heating, plasma or laser, to make the indium and tin precursors react to form the ITO film.

According to the aforementioned embodiments, one advantage of the present invention is that the atmospheric film-coating device and the film-manufacturing apparatus can coat the film under an atmospheric environment, so that the film can be rapidly coated on a substrate.

According to the aforementioned embodiments, another advantage of the present invention is that the atmospheric film-coating device and the film-manufacturing apparatus can simultaneously coat films on a large number of substrates, so that the throughput of the film can be greatly increased.

According to the aforementioned embodiments, still another advantage of the present invention is that the atmospheric film-coating device and the film-manufacturing apparatus can efficiently and uniformly coat the film on a continuous substrate.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. An atmospheric film-coating device, including:
a delivery device suitable for delivering at least one substrate; and
a nebulization device used to gasify a film coating solution toward a direction indirectly to the at least one substrate into a plurality of film coating vapor molecules to deposit on a surface of the at least one substrate.

2. The atmospheric film-coating device according to claim 1, further including a protective cover suitable for covering the at least one substrate and the nebulization device, wherein the protective cover and the delivery device define a confined space or a semi-confined space.

3. The atmospheric film-coating device according to claim 1, wherein the nebulization device includes:
at least one coating carrier suitable for carrying a film coating solution; and
at least one nebulization element disposed on the at least one coating carrier and suitable for gasifying the film coating solution into the film coating vapor molecules.

4. The atmospheric film-coating device according to claim 3, wherein the at least one nebulization element includes an ultrasonic nebulization vibration sheet, a heating evaporation nebulization element, a high-pressure gas jet element or a nozzle nebulization element.

5. The atmospheric film-coating device according to claim 3, wherein the at least one nebulization element is disposed on a top portion of the at least one coating carrier, and the nebulization device further includes at least one coating-conducting element suitable for inducing the film coating solution to the at least one nebulization element.

6. The atmospheric film-coating device according to claim 3, wherein the at least one coating carrier includes a plurality of coating carriers, and the at least one nebulization element includes one single nebulization element disposed on the coating carriers.

7. The atmospheric film-coating device according to claim 3, wherein the at least one coating carrier includes one single coating carrier, and the at least one nebulization element includes a plurality of nebulization elements disposed on the coating carrier.

8. The atmospheric film-coating device according to claim 1, wherein the delivery device further includes a carrier suitable for carrying the at least one substrate.

9. The atmospheric film-coating device according to claim 1, wherein an included angle between the direction and a gravitational direction of the at least one substrate ranges from 10 degrees to 180 degrees.

10. The atmospheric film-coating device according to claim 1, wherein an included angle between the direction and a gravitational direction of the at least one substrate ranges from 100 degrees to 170 degrees.

11. A film-manufacturing apparatus, including:
a delivery device suitable for delivering at least one substrate;
a plasma device disposed over the delivery device and suitable for performing a surface activation treatment on a surface of the at least one substrate; and
an atmospheric coating device adjacent to the plasma device, wherein the atmospheric coating device includes a nebulization device used to gasify a film coating solution toward a direction indirectly to the surface of the at least one substrate into a plurality of film coating vapor molecules to deposit on the surface of the at least one substrate.

12. The film-manufacturing apparatus according to claim 11, further including a protective cover suitable for covering the at least one substrate and the nebulization device, wherein the protective cover and the delivery device define a confined space or a semi-confined space.

13. The film-manufacturing apparatus according to claim 11, wherein the nebulization device includes:
at least one coating carrier suitable for carrying a film coating solution; and
at least one nebulization element disposed on the at least one coating carrier and suitable for gasifying the film coating solution into the film coating vapor molecules.

14. The film-manufacturing apparatus according to claim 13, wherein the at least one nebulization element includes an ultrasonic nebulization vibration sheet, a heating evaporation nebulization element, a high-pressure gas jet element or a nozzle nebulization element.

15. The film-manufacturing apparatus according to claim 13, wherein the at least one nebulization element is disposed on a top portion of the at least one coating carrier, and the nebulization device further includes at least one coating-conducting element suitable for conveying the film coating solution to the at least one nebulization element.

16. The film-manufacturing apparatus according to claim 13, wherein the at least one coating carrier includes a plurality of coating carriers, and the at least one nebulization element includes one single nebulization element disposed on the coating carriers.

17. The film-manufacturing apparatus according to claim 13, wherein the at least one coating carrier includes one single coating carrier, and the at least one nebulization element includes a plurality of nebulization elements disposed on the coating carrier.

18. The film-manufacturing apparatus according to claim 13, wherein the atmospheric coating device further includes a coating quantity sensor suitable for sensing a quantity of the film coating solution received in the at least one coating carrier.

19. The film-manufacturing apparatus according to claim 11, wherein the plasma device is an atmospheric plasma device, a low-pressure plasma device or an electromagnetically coupled plasma device.

20. The film-manufacturing apparatus according to claim 11, wherein an included angle between the direction and a gravitational direction of the at least one substrate ranges from 10 degrees to 180 degrees.
